(19) United States
(12) Patent Application Publication
(10) Pub. No.: US 2020/0266158 A1
(43) Pub. Date: Aug. 20, 2020

(54) HIGH PERFORMANCE THREE-DIMENSIONAL INTEGRATED CIRCUITS

(71) Applicant: Vathys, Inc., Portland, OR (US)

(72) Inventor: Tapabrata Ghosh, Portland, OR (US)

(21) Appl. No.: 16/277,864

(22) Filed: Feb. 15, 2019

(51) Int. Cl. H01L 23/64; H01L 21/822; H01L 27/06

(52) U.S. Cl. CPC H01L 23/642; H01L 27/0688; H01L 21/8221

(57) ABSTRACT

Disclosed are systems and methods to enable multi-layered integrated circuits having two or more layers, capable of communicating via capacitive link coupling. In some embodiments, the layers which include the electrodes of capacitive links can be stacked in face-to-face or face-to-back configuration.

### BACKGROUND

### Field of the Invention

This invention relates generally to the field of integrated circuits and more particularly to three-dimensional integrated circuits using capacitive link communication.

### Description of the Related Art

Recent slow-down in the development and prior success of two-dimensional chip manufacturing has renewed interest in three-dimensional chip manufacturing technology. Various communication methods exist to facilitate connection between multiple layers of a three-dimensional chip. Among them capacitive coupling has shown promise. Multi-layered chips that utilize capacitive coupling exist. Some are only limited to two layers placed in face-to-face configuration. Others use capacitive coupling pads, which add to area overhead of the IC and in practice prove inefficient. Consequently, there is a need for three-dimensional integrated circuits, where more than two layers can be stacked vertically and connected via capacitive coupling, without adding significant complexity or lowering system performance.

### SUMMARY

In one aspect of the invention, a three-dimensional integrated circuit is disclosed. The three-dimensional integrated circuit includes: a plurality of layers, wherein each layer comprises a substrate, wherein each substrate comprises a back surface and a face surface, wherein the back surface is an initial surface upon which circuitry is fabricated and the front surface is a final surface in which the circuitry is fabricated; one or more capacitive links enabling communication between one or more pairs of the plurality of layers, wherein the pairs are in face-to-back orientation in relation to each other.

In one embodiment, some pairs are in face-to-face orientation in relation to each other.

In one embodiment, the capacitance of the capacitive link is less than or equal to about 100 fF.

In some embodiments, a thickness of a substrate in the one or more pairs is less than or equal to about 100 um.

In one embodiment, the capacitance of the capacitive link is less than or equal to about 100 fF and a thickness of a substrate in the one or more pairs is less than or equal to about 100 um.

In some embodiments, a substrate in the one or more pairs is thinned using one or more of back-grinding, polishing, chemical mechanical planarization, chemical etching, electrochemical etching, gettering dry polishing, plasma etching, wet chemical etching, dry chemical etching and laser etching.

In some embodiments, one or more electrodes of the capacitive links are formed in one or more of a metal stack or back-end-of-line (BEOL), metal 1, metal 0, a transistor gate, a TSV, a transistor channel, a DSI metal stack, and a buried metal region.

In one embodiment, the capacitive links are formed via an alignment process and mechanically stabilized.

In one embodiment, the substrates are of a doping level and type to reduce or minimize charge loss in the substrate.

In another aspect of the invention, a method of building three-dimensional integrated circuits of two or more layers is disclosed. The method includes: placing a plurality of layers vertically on top of each other, wherein each layer comprises a substrate, wherein each substrate comprises a back surface and a face surface, wherein the back surface is an initial surface upon which circuitry is fabricated and the front surface is a final surface in which the circuitry is fabricated; forming one or more capacitive links enabling communication between one or more pairs of the plurality of layers, wherein the pairs are in face-to-back orientation in relation to each other.

In one embodiment, some pairs are in face-to-face orientation in relation to each other.

In one embodiment, the capacitance of the capacitive link is less than or equal to about 100 fF.

In one embodiment, a thickness of a substrate in the one or more pairs is less than or equal to about 100 um.

In one embodiment, the capacitance of the capacitive link is less than or equal to about 100 fF and a thickness of a substrate in the one or more pairs is less than or equal to about 100 um.

In some embodiments, a substrate in the one or more pairs is thinned using one or more of back-grinding, polishing, chemical mechanical planarization, chemical etching, electrochemical etching, gettering dry polishing, plasma etching, wet chemical etching, dry chemical etching and laser etching.

In some embodiments, forming the one or more capacitive links includes forming one or more electrodes of the capacitive links in one or more of a metal stack or back-end-of-line (BEOL), metal 1, metal 0, a transistor gate, a TSV, a transistor channel, a DSI metal stack, and a buried metal region.

In one embodiment, forming the one or more capacitive links includes forming them via an alignment process and mechanically stabilizing them.

In one embodiment, the substrates are of a doping level and type to reduce or minimize charge loss in the substrate.

### BRIEF DESCRIPTION OF THE DRAWINGS

These drawings and the associated description herein are provided to illustrate specific embodiments of the invention and are not intended to be limiting.

FIG. 1 illustrates a portion of a three-dimensional integrated circuit using communication via capacitive link according to an embodiment.

FIG. 2 illustrates an example diagram of capacitive links according to an embodiment.

FIG. 3 illustrates a capacitive link portion of a three-dimensional chip with more than two layers according to an embodiment.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail. When the terms “one”, “a” or “an” are used in the disclosure, they mean “at least one” or “one or more”, unless otherwise indicated.

The term “about” as used herein refers to the ranges of specific measurements or magnitudes disclosed. For example, the phrase “about 10” means that the number stated may vary as much as 1%, 3%, 5%, 7%, 10%, 15% or 20%. Therefore, at the variation range of 20% the phrase “about 10” means a range from 8 to 12.

The roots of three-dimensional (3D) integration of semiconductor integrated circuits (ICs) date as far back as the early days of manufacturing integrated circuits using semiconductor material. However, interest in 3D integration waned as two-dimensional (2D) manufacturing techniques experienced tremendous growth and success. Recently, the slow-down in Moore's law, breaking down of Dennard's scaling and problems with scaling on-chip wires have led to a renewed interest in 3D chips. As a result, three-dimensional integration of integrated circuits has been the subject of intensive research in recent years. Out of these efforts, two main approaches of manufacturing three-dimensional circuits have emerged. One approach may be referred to as “monolithic 3D” or “Sequential 3D.” In monolithic 3D integration, layers of circuitry are deposited on one another, layer by layer in a monolithic process using IC fabrication methods. A second approach may be referred to as “parallel 3D.” In parallel 3D integration, several substantially pre-manufactured 2D or 3D chips are aligned on top of each other, mechanically stabilized and interconnected with various techniques, such as through silicon via (TSV) and inductive coupling.

TSV interconnect and inductive coupling present technical challenges. For example, they can be relatively slow, take up large chip area and consume high power. Communication via capacitive coupling between chip layers promises to address some of the shortcomings of TSVs and inductive coupling. However, existing methods of capacitive coupling include drawbacks that have slowed down the adoption of capacitive coupling in 3D chips. For example, one method, referred to as “proximity communication” using capacitive coupling only allows stacking two chips vertically in face-to-face configuration. This can eliminate benefits of three-dimensional integration, which may otherwise be available if more than two layers can be stacked and in other orientations such as face to back. Additionally, power delivery in chips made using proximity communication method has proven difficult.

Attempts have been made to stack more than two layers and connect them with capacitive coupling. One approach is to use pads to create capacitive coupling (e.g., the method used in through silicon capacitive coupling (TSCC)). Technical challenges exist when using such methods. For example, the area overhead associated with using TSCC pads can be prohibitive (e.g., in some cases one thousand microns), which can significantly hinder the usage of such devices in high performance, low power consumption applications.

Some technical challenges of prior art systems can be because of the relatively large electrode separation distance between plates of capacitors where large substrate thickness of about 400 micrometers (um) are typical. Many existing 3D chips attempting communication via capacitive links utilize standard-size substrate wafers, which can be too thick for useful capacitive connections. For example, too much electrode separation distance can lead to exponential channel capacity loss. The disclosed embodiments utilize a thinned wafer substrate (e.g., substrate thickness of less than about 100 um) to overcome these limitations in existing devices.

Other existing devices that use a relatively large substrate and large electrode area can be more prone to significant noise and cross talk as the substrate absorbs more and more charge over large electrode areas. In addition to enabling more than two layers in a 3D chip, the disclosed embodiments use of thin substrates, enables use of smaller electrode areas. Using smaller electrode areas, in turn, substantially reduces cross talk and noise between layers of a 3D chip.

Another technical challenge in some prior art devices can be high capacitance of the capacitive link, which can reduce the efficiency of capacitive coupling and the overall system performance. The disclosed embodiments utilize a capacitive link with capacitance less than about 100 femtofarad (fF), which can address the issues described above.

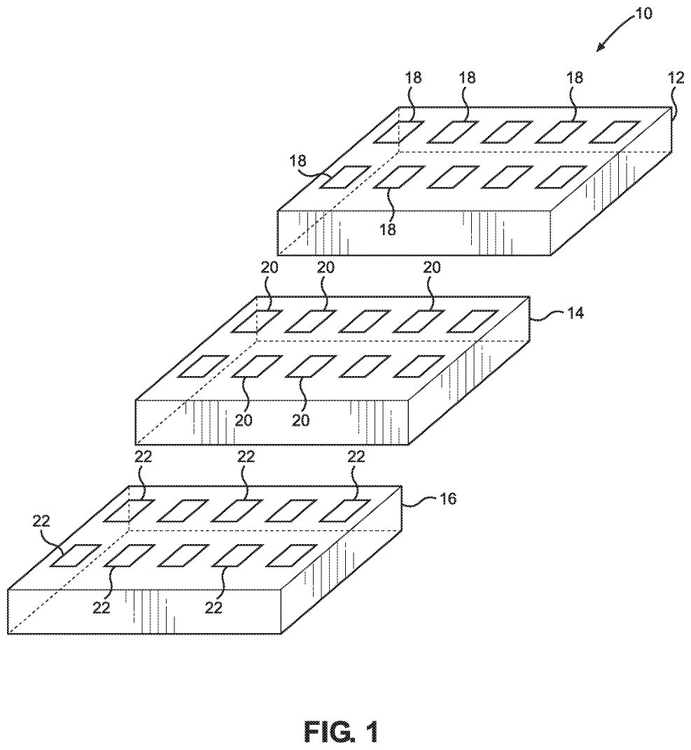

FIG. 1 illustrates a portion 10 of a multilayered 3D IC which utilizes capacitive coupling to create communication and/or connection between the multiple layers of the multilayered 3D IC. The portion 10 includes layers 12, 14 and 16 placed vertically on top of each other. While three layers are shown for brevity purposes, two layers, or more than three layers are possible. The layers 12, 14 and 16 can each be a portion of a larger layer of the multilayered 3D IC, which can encompass a variety of circuitry, such as logic, memory, transistors, resistors, inductors, capacitors and other electrical components that may be present in a 3D IC. The layers 12, 14 and 16 each include one or more capacitive plates 18, 20 and 22, respectively.

The arrangements and layout of the capacitive plates 18, 20 and 22 can vary depending on the implementation and design of the multilayered IC, which incorporates the portion 10. For example, layers 12, 14 and 16 may be offset by an amount to create some parallel plate capacitive coupling between layers 12 and 14 and some parallel plate capacitors between layers 14 and 16. In some embodiments, non-adjacent layers 12 and 16 may form capacitive coupling via parallel plates 18 and 22. A variety of configurations and layouts are available to manufacture a multi-layered 3D IC incorporating the portion 10.

The portion 10 illustrates the layers 12, 14 and 16 in a face to back configuration. Layers 12, 14 and 16 can be substrates (e.g., silicon wafers) upon which various circuitry is fabricated. While not shown, each layer 12, 14, and 16 can include various internal layers, including metal layer, semiconductor layer, insulator layer, channels and/or other features that make up various functionality implemented by the circuitry in layers 12, 14 and 16. The bottom surface of a layer/substrate upon which various processing and fabrication layers of circuitry are grown, deposited and/or otherwise built can be referred to as the back surface of the layer/substrate. The top and uppermost surface of the layer/substrate relative to the back surface of that layer/substrate can be referred to as the face surface. In other words, the initial surface of a silicon wafer substrate upon which circuitry is fabricated can be referred to as the back surface and the final surface in which circuitry is fabricated can be referred to as the face surface.

As described earlier, existing devices with configurations other than face-to-face have been either impossible (e.g., in two-layered 3D ICs using proximity communication) and/or are fraught with technical drawbacks (e.g., large area and power consumption in TSCC). Additionally, face-to-face 3D integration makes fabricating some chip functionality and circuitry more difficult. For example, power connections, and bonding wires are difficult to implement in face-to-face chips. The disclosed embodiments, enable stacking more than two layers in other orientations and configurations, such as back to face, face to back and back to back, without the technical challenges of the existing devices. Additionally, a mix of layer orientations may be present in a 3D IC, where some layers are in face-to-face, some layers are in back-to-face, and some layers are in back-to-back orientation and/or other combinations.

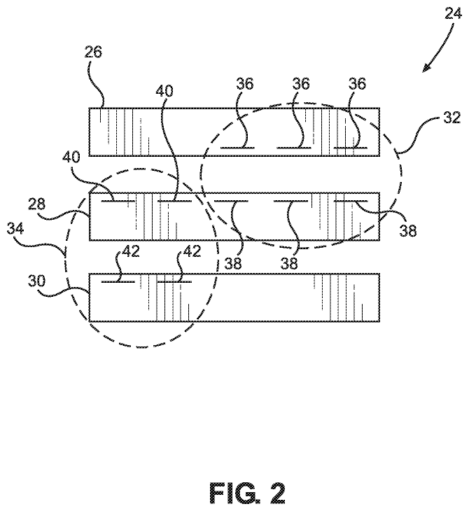

FIG. 2 illustrates another example layout diagram of a capacitive link portion 24 of a 3D IC. Three layers 26, 28 and 30 stacked on top of each other in vertical direction are shown for illustration purposes. Two layers or more than three layers are also possible. Layer 26 is connected to and can communicate with the layer 28 via the capacitive link 32. Layer 28 is also connected to and can communicate with the layer 30 via capacitive link 34. Layer 26 is in a face to face orientation with respect to layer 2, while layer 28 is in a back-to-face orientation with respect to layer 30. Capacitive link 32 is formed by one or more plates 36 in layer 26 and one or more plates 38 in layer 28. Capacitive link 34 is formed by one or more plates 40 in layer 28 and one or more plates 42 in layer 30.

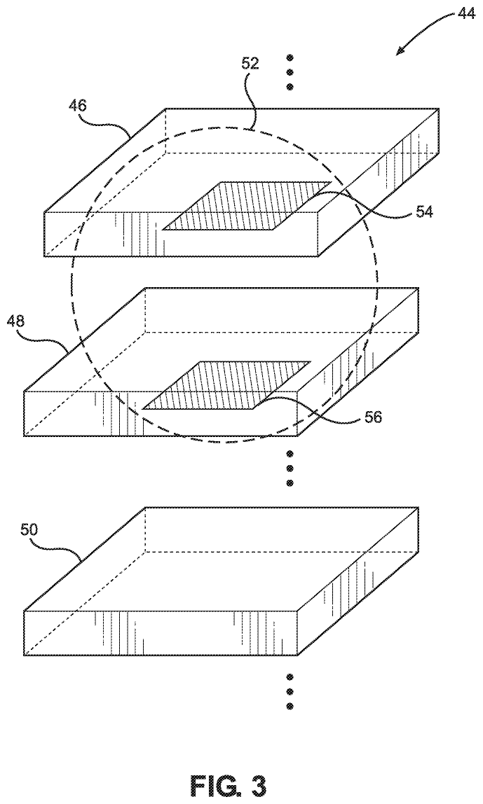

FIG. 3 illustrates a capacitive link portion 44 of a 3D chip with more than two layers. Layers 46, 48 and 50 are shown for illustration purposes, but two layers or more than three layers are also possible. Layers 46 and 48 are staked vertically, in face-to-back orientation and are connected via capacitive link 52. Capacitive link 52 is formed by plate 54 in layer 46 and plate 56 in layer 48. While one capacitive link 52 with two parallel plates 54 and 56 are shown for illustration purposes, the principles discussed in relation to FIG. 3 and previous embodiments and figures can be applied to a variety of configurations, orientations and arrangements of multilayered chips.

One or more of substrates 46 and 48 can be thinned to a thickness of less than or equal to about 100 um and the link capacitance 52 can be formed to be of capacitance of less than or equal to about 100 if. Such a configuration enables stacking more than two layers in a 3D chip, where layers can be in face-to-back (or other desired) orientation, allowing easier fabrication of other circuitry in each layer and easier access for fabricating connections within and between each layer. The lower limit of the capacitance of the capacitive link 52 can depend on a variety of factors including the fabrication process used to build the capacitive link 52 and the sense and receive circuitry (Tx/Rx) implemented by the capacitive link 52. In some applications the capacitance of the capacitive link 52 can be as low as 1 fF and not prone to noise and process variation challenges. The lower limit of the substrate thickness can depend on physical limitation of the material used for the substrate and the ability of the process to achieve a desired thinness.

Additionally, the disclosed substrate thickness and capacitance enable reduced cross talk and noise, reduced energy consumption, increased bandwidth and overall chip performance. In simulation tests, a device incorporating the principles described above achieved the following performance figures relative to existing TSCC devices. The proposed device was able to achieve 50 Gbps and 0.1 fJ/bit for a 20 nm thick substrate, which is about 250 times higher bandwidth per channel and about 10,000 times lower in power consumption and about 140 million times higher bandwidth per unit of area.

Various locations and features within or between layers of a 3D chip can be used to form or fabricate the capacitive link 52 and its electrodes. For example, the metal stack/back-end-of-line (BEOL), metal 1 and/or metal 0, a transistor gate, a TSV (the end can be used as an electrode, especially with a higher width to height aspect ratio), a transistor channel, a double-sided integration (DSI) metal stack (which is another metal stack below transistors), a buried metal region, etc. Additionally, a combination of the above locations and/or features can be used to form or fabricate one or more capacitive links to achieve communication between layers. In 3D chips using DSI, one metal layer can exist below the transistor layer and one metal layer can exist above the transistor layer. In addition to providing a potential candidate for the electrodes of the capacitive link 52, DSI can help reduce contact pin contention, metal 1 routing congestion and make 3D stacking much easier.

A variety of techniques can be used to form the capacitive link 52. For example, an alignment process (e.g., alignment keys, infrared (IR) alignment, double backside alignment, etc.) can be used. A variety of mechanical connections, for example, epoxies, adhesives, Benzocyclobutene (BCB) adhesives, direct bonding, hybrid bonding, metal-metal bonding, anodic bonding, thermocompression bonding, etc. can be used to provide mechanical stability.

Furthermore, the substrates 46, 48, 50 and/or substrates used to create capacitive links can be thinned using a variety of techniques. Examples include, back-grinding, polishing, chemical mechanical planarization, chemical etching, electrochemical etching, gettering dry polishing, plasma etching, wet chemical etching, dry chemical etching and/or laser etching.

Additionally, various substrate resistivities can be used to improve the performance of the capacitive link 52. Substrate resistivities refer to using various materials and/or doping levels to achieve a desired bulk resistivity of a substrate. In some applications, capacitive coupling in the face to back orientation can be limited by the low S21 transfer characteristics due to charge loss in a silicon substrate. This is because silicon is not purely an insulator, especially not when it is doped relatively heavily as the p-type wafers used in semiconductor processing are. The low S21 transfer characteristics has also been a factor in slowing the commercial adoption and application of capacitive coupling in face to back configuration. A wide range of substrate resistivities can be used to achieve face to back capacitive coupling. For example, in some applications, the standard P+ wafers used in typical fabrication processed can be replaced with a substrate with a doping level targeted to increase the S21 transfer characteristics of the substrate. In some applications a variety of substrate types can be used. An example substrate which can be used is a silicon on insulator (SOI) wafer.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first, second, other and another and the like may be used solely to distinguish one entity or action from another without necessarily requiring or implying any actual such relationship or order between such entities or actions.

The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

What is claimed is:

1. A three-dimensional integrated circuit, comprising:
a plurality of layers, wherein each layer comprises a substrate, wherein each substrate comprises a back surface and a face surface, wherein the back surface is an initial surface upon which circuitry is fabricated and the front surface is a final surface in which the circuitry is fabricated;
one or more capacitive links enabling communication between one or more pairs of the plurality of layers, wherein the pairs are in face-to-back orientation in relation to each other.

2. The integrated circuit of claim 1, wherein some pairs are in face-to-face orientation in relation to each other.

3. The integrated circuit of claim 1, wherein the capacitance of the capacitive link is less than or equal to about 100 fF.

4. The integrated circuit of claim 1, wherein a thickness of a substrate in the one or more pairs is less than or equal to about 100 um.

5. The integrated circuit of claim 1, wherein the capacitance of the capacitive link is less than or equal to about 100 fF and a thickness of a substrate in the one or more pairs is less than or equal to about 100 um.

6. The integrated circuit of claim 1, wherein a substrate in the one or more pairs is thinned using one or more of back-grinding, polishing, chemical mechanical planarization, chemical etching, electrochemical etching, gettering dry polishing, plasma etching, wet chemical etching, dry chemical etching and laser etching.

7. The integrated circuit of claim 1, wherein one or more electrodes of the capacitive links are formed in one or more of a metal stack or back-end-of-line (BEOL), metal 1, metal 0, a transistor gate, a TSV, a transistor channel, a DSI metal stack, and a buried metal region.

8. The integrated circuit of claim 1, wherein the capacitive links are formed via an alignment process and mechanically stabilized.

9. The integrated circuit of claim 1, wherein the substrates are of a doping level and type to reduce or minimize charge loss in the substrate.

10. A method of building three-dimensional integrated circuits of two or more layers, comprising:
placing a plurality of layers vertically on top of each other, wherein each layer comprises a substrate, wherein each substrate comprises a back surface and a face surface, wherein the back surface is an initial surface upon which circuitry is fabricated and the front surface is a final surface in which the circuitry is fabricated;
forming one or more capacitive links enabling communication between one or more pairs of the plurality of layers, wherein the pairs are in face-to-back orientation in relation to each other.

11. The method of claim 10 wherein some pairs are in face-to-face orientation in relation to each other.

12. The method of claim 10, wherein the capacitance of the capacitive link is less than or equal to about 100 fF.

13. The method of claim 10, wherein a thickness of a substrate in the one or more pairs is less than or equal to about 100 um.

14. The method of claim 10, wherein the capacitance of the capacitive link is less than or equal to about 100 fF and a thickness of a substrate in the one or more pairs is less than or equal to about 100 um.

15. The method of claim 10, wherein a substrate in the one or more pairs is thinned using one or more of back-grinding, polishing, chemical mechanical planarization, chemical etching, electrochemical etching, gettering dry polishing, plasma etching, wet chemical etching, dry chemical etching and laser etching.

16. The method of claim 10, wherein forming the one or more capacitive links comprises forming one or more electrodes of the capacitive links in one or more of a metal stack or back-end-of-line (BEOL), metal 1, metal 0, a transistor gate, a TSV, a transistor channel, a DSI metal stack, and a buried metal region.

17. The method of claim 10, wherein forming the one or more capacitive links comprises forming them via an alignment process and mechanically stabilizing them.

18. The method of claim 10, wherein the substrates are of a doping level and type to reduce or minimize charge loss in the substrate.
